(19) United States
(12) Patent Application Publication
(10) Pub. No.: US 2015/0311430 A1
(43) Pub. Date: Oct. 29, 2015

(54) MAGNETORESISTIVE SENSOR

(71) Applicant: Seagate Technology LLC, Cupertino, CA (US)

(72) Inventors: Eric W. Singleton, Maple Plain, MN (US); Liwen Tan, Eden Prairie, MN (US); Jae-Young Yi, Prior Lake, MN (US); Konstantin Nikolaev, Bloomington, MN (US)

(73) Assignee: Seagate Technology LLC, Cupertino, CA (US)

(21) Appl. No.: 14/263,146

(22) Filed: Apr. 28, 2014

(51) Int. Cl. H01L 43/08; H01L 43/10; H01L 43/02

(52) U.S. Cl. CPC H01L 43/08; H01L 43/02; H01L 43/10

(57) ABSTRACT

Implementations disclosed herein provide a magnetoresistive (MR) sensor including a free layer comprising a first layer of CoFeB or CoFe/CoFeB and a second layer made of an alloyed layer including a ferromagnetic material and a refractory material. An implementation of the MR sensor further includes a cap layer adjacent to the second layer wherein the cap layer does not include any tantalum.

### BACKGROUND

In a magnetic data storage and retrieval system, a magnetic read/write head includes a reader portion having a magnetoresistive (MR) sensor for retrieving magnetically encoded information stored on a magnetic disc. Magnetic flux from the surface of the disk causes rotation of a magnetization vector of a sensing layer of the MR sensor, which in turn causes a change in electrical resistivity of the MR sensor. The change in resistivity of the MR sensor can be detected by passing a current through the MR sensor and measuring a voltage change across the MR sensor. External circuitry then converts the voltage information into an appropriate format and manipulates that information to recover the information encoded on the disc.

Improvements in magnetic storage media and head technology allow areal recording densities on magnetic discs that are available today. However, as areal recording densities increase, smaller, more sensitive MR sensors are desired. As MR sensors become smaller in size, the MR sensors have potential to exhibit an undesirable magnetic response to applied fields from the magnetic disc. An effective MR sensor may reduce or eliminate magnetic noise and provide a signal with adequate amplitude for accurate recovery of the data written on the disc.

### SUMMARY

Implementations disclosed herein provide a magnetoresistive (MR) sensor including a free layer comprising a first layer of CoFeB or CoFe/CoFeB and a second layer made of an alloyed layer including a ferromagnetic material and a refractory material. An implementation of the MR sensor further includes a cap layer adjacent the second layer wherein the cap layer does not include any tantalum.

This Summary is provided to introduce an election of concepts in a simplified form that are further described below in the Detailed Description. This Summary is not intended to identify key features or essential features of the claimed subject matter, nor is it intended to be used to limit the scope of the claimed subject matter. Other features, details, utilities, and advantages of the claimed subject matter will be apparent from the following more particular written Detailed Description of various implementations and implementations as further illustrated in the accompanying drawings and defined in the appended claims.

### BRIEF DESCRIPTIONS OF THE DRAWINGS

FIG. 1 illustrates a plan view of an example disk drive assembly including an MR sensor disclosed herein.

FIG. 2 illustrates an example MR sensor including a free layer including a layer of alloyed material.

FIG. 3 illustrates an alternative example implementation of the MR sensor including a free layer including a layer of alloyed material.

FIG. 4 illustrates an example graph of normalized tunneling magneto-resistance (TMR) for an MR sensor disclosed herein.

FIG. 5 illustrates an alternative example graph of normalized TMR for an MR sensor disclosed herein.

FIG. 6 illustrates example operations for forming the MR sensor stack disclosed herein.

### DETAILED DESCRIPTION

There is an increasing demand for high areal densities and sensitive sensors to read data from a magnetic media. Giant Magnetoresistive (GMR) sensors that have increased sensitivity consist of two soft magnetic layers separated by a thin conductive, non-magnetic spacer layer such as copper. Tunnel Magnetoresistive (TMR) sensors provide an extension to GMR in which the electrons travel with their spins oriented perpendicularly to the layers across a thin insulating tunnel barrier. An antiferromagnetic (AFM) material is placed adjacent to the first soft magnetic layer to prevent it from rotating. AFM materials exhibiting this property are termed “pinning materials.” With its rotation inhibited, the first soft layer is termed the “pinned layer.” The second soft layer rotates freely in response to an external field and is called the “free layer” (FL). In some configurations, the AFM material may comprise a synthetic antiferromagnet (SAF) consisting of multiple thin ferromagnetic layers, one or more layer pairs being separated by a thin nonmagnetic layer. In this manner, a SAF may be employed to pin the magnetizing vector of the pinned layer.

The FL may include first soft magnetic layer adjacent to a barrier layer and a second soft magnetic layer adjacent to a cap layer. To control the magnetostriction, and therefore the stability of the read sensor, the free layer adjacent to the cap layer may be a NiFe layer. However, including the NiFe layer causes diffusion of the nickel during annealing of the sensor structure to the free layer adjacent the barrier layer, which decreases the spin-polarization effect of the sensor. Furthermore, the diffusion of the nickel into the free layer adjacent to the barrier layer also hinders that microstructure formation of this free layer. To maximize TMR during formation of the MR sensor, some sensor designs include the two individual soft magnetic layers laminated together by a thin non-magnetic insertion layer that prevents microstructural interference and diffusion between these two soft magnetic layers at high temperature annealing process.

For example, such thin non-magnetic insertion layer between the two free layers may be a thin tantalum layer. This thin tantalum layer separates the microstructure of the first and the second soft magnetic layer and improves TMR in the MR sensor. Although such non-magnetic materials, such as tantalum, are effective at separating the microstructure of the soft magnetic layers, non-magnetic materials can dilute the magnetic moment or flux of the adjacent soft magnetic layers and weakens or even decouples the two free layers from each other. Such decoupling results in degradation of the signal-to-noise (SNR) of the MR sensor.

To avoid the diluting and decoupling effects of such an insertion layer, an implementation of an MR sensor disclosed herein includes a free layer that does not include any layer of non-ferromagnetic material such as tantalum. Specifically, such implementation of the free layer includes a first layer made of CoFeB or CoFe/CoFeB and a second layer made of an alloy of a ferromagnetic material and a refractory material (X). The ferromagnetic material may be, for example, Co, Fe, and CoFe, and the refractory material may be, for example, Ta, Nb, Hf, Zr, etc. In one implementation, the alloyed layer has X in the range of 1-30%. In one implementation, the alloy of a ferromagnetic material and a refractory material (X) may be sputtered on top of the CoFeB or CoFe/CoFeB layer to form the second layer.

Examples of the alloy of a ferromagnetic material and a refractory material (X) may include materials that have soft magnetic properties with relatively low magnetostriction. For example, in one implementation, the magnetostriction of the alloy is in the range of −10⁻⁵ to 10⁻⁵. Furthermore, the alloy may be amorphous and may have a mill rate close to the mill rate of the ferromagnetic materials, such as CoFe, etc. In one implementation, the first layer of FL, made of CoFeB or CoFe/CoFeB is formed adjacent to a barrier layer, such as a textured MgO barrier. As alloy of a ferromagnetic material (e.g., CoFe) and a refractory material (X) is amorphous, it does not affect the formation of a coherent textured structure between the MgO barrier layer and the CoFeB layer.

Furthermore, as the free layer does not include any NiFe layer, the sensor structure layers may be annealed at a higher temperature without any concern about diffusion of the nickel in other free layer. The higher temperature annealing also results in better microstructure formation and therefore better TMR for the sensor structure. For example, a sensor structure having a free layer including a layer that is made of an alloy of a ferromagnetic material (e.g., CoFe) and a refractory material (X) may be annealed at as high temperature as 350 degrees centigrade.

Furthermore, using an upper free layer that is made of an alloy of ferromagnetic material (e.g., CoFe) and a refractory material (X) allows providing a cap layer that does not include any tantalum. For example the cap layer may be made of a layer of ruthenium and a layer of noble material that does not oxidize. Alternatively, the cap layer may be made of a layer of ruthenium adjacent to the free layer and a layer of platinum. As the noble layers do not oxidize easily, they reduce the process variations during formation of the sensor structure that may occur due to the oxidization of a layer in the cap layer. Other materials that may be used in place of platinum may include, for example silver, gold, etc., that does not oxidize.

In yet alternative implementation, the cap layer may include only a single layer. Such single layer may be made of noble material such as platinum, gold, rhodium, iridium, silver, palladium, etc., that does not oxidize easily. Using the cap layer made of only one layer reduces the down-track thickness of the cap layer therefore reducing the down-track thickness of a sensor structure. Reducing the down-track thickness of a sensor structure also results in reduction of shield-to-shield spacing (SSS) and improving resolution of the MR sensor.

The technology disclosed herein may be used in conjunction with a variety of different types of MR sensors (e.g., anisotropic magnetoresistive (AMR) sensors, TMR sensors, GMR sensors, etc.). Accordingly, the implementations discussed may also be applicable to new MR sensor designs that are based on new physical phenomena such as lateral spin valve (LSV), spin-hall effect (SHE), spin torque oscillation (STO), etc.

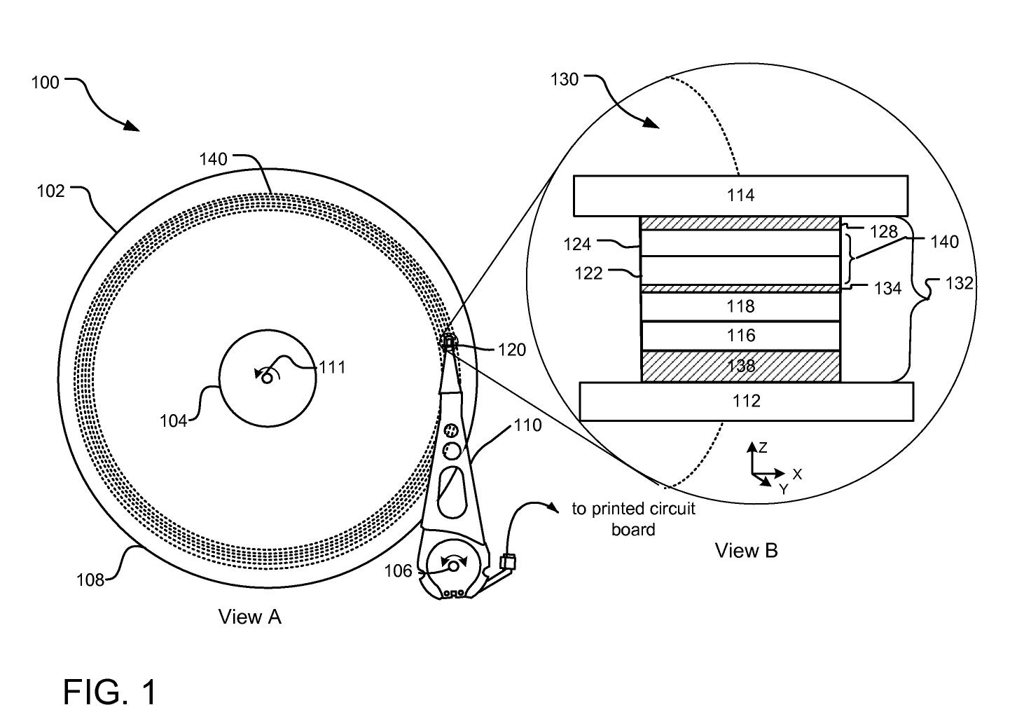

FIG. 1 illustrates a plan view of an example disk drive assembly 100. The example disk drive assembly 100 includes a slider 120 on a distal end of an actuator arm 110 positioned over a media disk 108. A rotary voice coil motor that rotates about an actuator axis of rotation 106 is used to position the slider 120 on a data track (e.g., a data track 140) and a spindle motor that rotates about disk axis of rotation 111 is used to rotate the media disk 108. Referring specifically to View A, the media disk 108 includes an outer diameter 102 and an inner diameter 104 between which are a number of data tracks, such as the data track 140, illustrated by circular dotted lines. A flex cable (not shown) provides the requisite electrical connection paths for the slider 120 while allowing pivotal movement of the actuator arm 110 during operation.

The slider 120 may be a laminated structure with a variety of layers performing a variety of functions. The slider 120 includes a writer section (not shown) and one or more MR sensors for reading data off of the media disk 108. View B illustrates a side of an example MR sensor 130 that faces an air-bearing surface (ABS) of the media disk 108 when the disk drive assembly 100 is in use. Thus, the MR sensor 130 shown in view B may be rotated by about 180 degrees about (e.g., about a z-axis) when operationally attached to the slider 120 shown in View A.

The MR sensor 130 utilizes magnetoresistance to read data from the media disk 108. While the precise nature of the MR sensor 130 may vary widely, a tunneling magneto-resistive (TMR) sensor is described as one example of an MR sensor that can be utilized with the presently-disclosed technology.

The MR sensor 130 includes a sensor stack 132 positioned between a top shield 114 and a bottom shield 112. The top shield 114 and the bottom shield 112 isolate the sensor stack 132 from electromagnetic interference, primarily z-axis or down-track interferences, and serve as electrically conductive first and second electrical leads connected to processing electronics (not shown). In one implementation, the bottom shield 112 and the top shield 114 permit the MR sensor 130 to be affected by magnetic fields of a data bit directly under the MR sensor 130 while reducing or blocking magnetic field interference of other, adjacent data bits. Therefore, as the physical size of bits continues to decrease, the spacing between the top shield 114 and the bottom shield 112, also known as the shield-to-shield spacing (SSS), should also be decreased.

The sensor stack 132 includes a seed layer 138 that initiates a desired grain structure in other layers of the sensor stack 132. The seed layer 138 may be made of a magnetic material or non-magnetic material such as Ta, Ru, etc.

The sensor stack 132 also includes a synthetic antiferromagnetic (SAF) layer formed on an AFM layer 116, where the SAF layer includes a pinned layer (both referred together as the SAF layer 118. The AFM layer 116 pins the magnetic orientation of one or more of the SAF layer 118. For example, in one implementation, the SAF layer 118 is a soft magnetic layer with a magnetic orientation biased in a given direction by the AFM layer 116.

The MR sensor 130 further includes a free layer structure 140 that has a magnetic moment that is free to rotate under the influence of an applied magnetic field in the range of interest. The free layer structure 140 is separated from the SAF layer 118 by a tunneling barrier layer 134. The tunneling barrier layer 134 may be made of, for example, a textured MgO barrier.

The tunneling barrier layer 134 separates the SAF layer 118 from the free layer structure 140. The tunneling barrier layer 134 is sufficiently thin to enable quantum mechanical electron tunneling between the SAF layer 118 and the free layer structure 140. The electron tunneling is electron-spin dependent, making the magnetic response of the MR sensor 130 a function of the relative orientations and spin polarizations of the free layer structure 140 and of the SAF layer 118. The lowest probability of electron tunneling occurs when the magnetic moments of the SAF layer 118 and the free layer structure 140 are antiparallel. Accordingly, the electrical resistance of the sensor stack 132 changes in response to an applied magnetic field.

According to one implementation disclosed herein, the free layer structure 140 includes a first free layer (FL1) 122 and a second free layer (FL2) 124 adjacent each other. Specifically, the FL1 122 is in contact with or adjacent to the tunneling barrier layer 134. Furthermore, there is no separating layer between the FL1 122 and the FL2 124. In other words, the FL1 122 and the FL2 124 are adjacent or in contact with each other.

According to one implementation disclosed herein, the free layer structure 140 does not include any layer of non-ferromagnetic material such as tantalum. Specifically, in such implementation of the free layer structure 140 the FL1 122 is made of CoFeB or CoFe/CoFeB layers and the FL2 124 is made of an alloy of a ferromagnetic material and a refractory material (X). The ferromagnetic material may be, for example, Co, Fe, and CoFe, and the refractory material may be, for example, Ta, Nb, Hf, Zr, etc. In one implementation, the alloyed layer has X in the range of 1-30%. In one implementation, the alloy of a ferromagnetic material and a refractory material (X) may be sputtered on top of the CoFeB or CoFe/CoFeB layer to form the second layer.

Examples of the alloy of a ferromagnetic material and a refractory material (X) that may be used in FL2 124 may include materials that has soft magnetic properties with relatively low magnetostriction. For example, in one implementation, the magnetostriction of the alloy of a ferromagnetic material and a refractory material (X) is in the range of −10⁻⁵ to 10⁻⁵. Furthermore, the alloy of a ferromagnetic material and a refractory material (X) may be amorphous and may have a mill rate close to the mill rate of the ferromagnetic materials, such as CoFe, etc. In one implementation, the first FL of CoFeB or CoFe/CoFeB is formed adjacent to a barrier layer, such as a textured MgO barrier. As alloy of a ferromagnetic material (e.g., CoFe) and a refractory material (X) is amorphous, it does not affect the formation of a coherent textured structure between the MgO barrier layer and the CoFeB layer.

Furthermore, as the free layer structure 140 does not include any NiFe layer, the layers of the MR sensor 130 may be annealed at a higher temperature without any concern about diffusion of the nickel into other FL1 122. The higher temperature annealing also results in better microstructure formation and therefore better TMR for the MR sensor 130. For example, a sensor structure having a free layer including a layer that is made of an alloy of a ferromagnetic material (e.g., CoFe) and a refractory material (X) may be annealed at as high temperature as 350 degrees centigrade.

The sensor stack 132 further includes a capping layer 128. The capping layer 128 magnetically separates the free layer structure 140 from the top shield 114. The capping layer 128 may include several individual layers (not shown). Providing FL2 124 that is made of an alloy of ferromagnetic material (e.g., CoFe) and a refractory material (X) allows providing a capping layer 128 that does not include any tantalum. For example the capping layer 128 may be made of a layer of ruthenium and a layer of noble material that does not oxidize. Alternatively, the capping layer 128 may be made of a layer or ruthenium adjacent to the FL2 124 and a layer of platinum. As the noble layers do not oxidize easily, they reduce the process variations during formation of the MR sensor 130 that may occur due to the oxidization of a layer in the capping layer 128. Other materials that may be used in place of platinum may include, for example silver, gold, etc., that does not oxidize.

In yet alternative implementation, the capping layer 128 may include only a single layer. Such single layer may be made of noble material such as platinum, gold, rhodium, iridium, silver, palladium, etc., that does not oxidize easily. Using the capping layer 128 made of only one layer reduces the down-track thickness of the capping layer 128 and therefore reducing the down-track thickness of the MR sensor 130. Reducing the down-track thickness of a MR sensor 130 also results in reduction of shield-to-shield spacing (SSS) and improving resolution of the MR sensor 130.

The data bits on the media disk 108 are magnetized in a direction normal to the plane of FIG. 1, either into the place of the figure, or out of the plane of the figure. Thus, when the MR sensor 130 passes over a data bit, the magnetic moment of the free layer structure is rotated either into the plane of FIG. 1 or out of the plane of FIG. 1, changing the electrical resistance of the MR sensor 130. The value of the bit being sensed by the MR sensor 130 (e.g., either 1 or 0) may therefore be determined based on the current flowing from a first electrode coupled to the AFM layer 116 and to a second electrode coupled to the capping layer 128.

Amorphous magnetic materials suitable for use in the FL2 124 may also exhibit one or more of the following properties: magnetic softness, relatively low magnetostriction, and a mill rate that is substantially the same as the mill rate of one or more other soft magnetic materials (e.g., CoFe) used in the MR sensor 130. In one implementation, a suitable amorphous magnetic material has a magnetostriction coefficient between −1.0⁻⁵ and +1.0-⁵.

The amorphous magnetic material may be an alloy that includes a ferromagnetic material, such as Co, Fe or CoFe, and a refractory material, such as Ta, Nb, Hf, Zr, etc. For example, the alloy may be CoFeX, where X is a refractory material. The alloy may include between 1 and about 30% of the refractory material, or enough to ensure that the alloy is amorphous. In one example implementation, the alloy is CoFeTa and comprises 10-25% Ta. The percent of refractory material included in the amorphous magnetic material is a variable value that may depend upon the refractory material and ferromagnetic material used in such alloy.

As used herein, “amorphous” refers to a solid that lacks the long-range order characteristic of a crystal. The amorphous magnetic material may be deposited as a thin film and remain amorphous during post-deposition processing, such as during a magnetic annealing process.

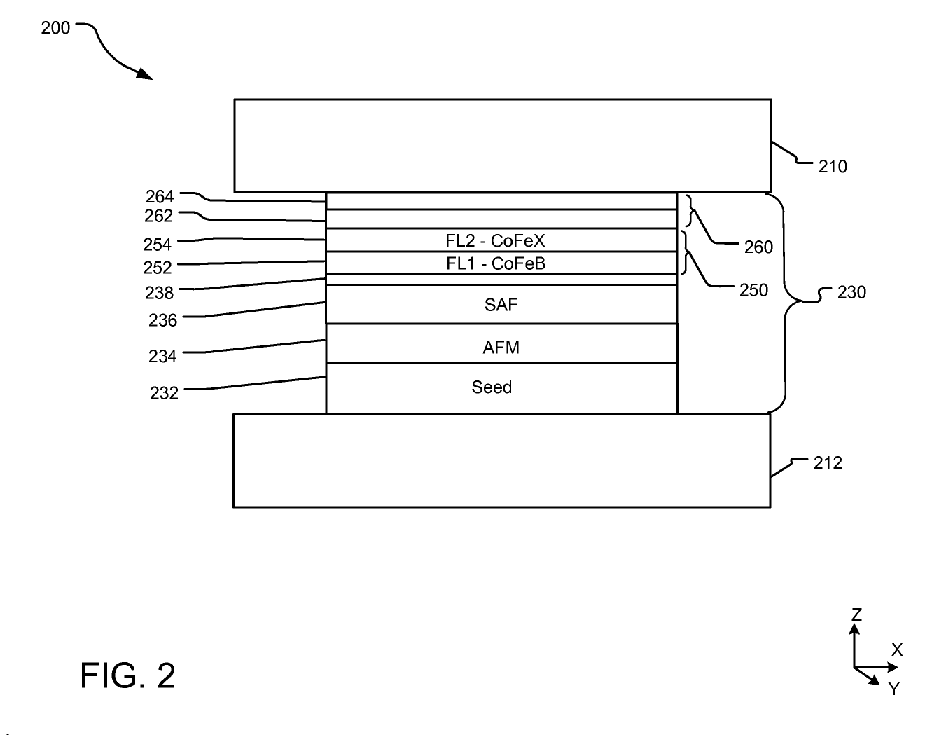

FIG. 2 illustrates an example MR sensor 200 including a free layer including a layer of alloyed material. The MR sensor 200 includes a sensor stack 230 located along a down-track (z axis) direction between a bottom shield 212 and a top shield 210. The sensor stack 230 includes a seed layer 232, an AFM layer 234, a SAF layer 236, a tunneling barrier layer 238, a free layer structure 250, and a capping layer structure 260. In the illustrated implementation, the free layer structure 250 includes a lower free layer FL1 252 that is made of CoFeB or CoFe/CoFeB layers and an upper free layer FL2 254 that is made of an alloy of a ferromagnetic material and a refractory material (X). Furthermore, the free layer structure 250 does not include any layer of tantalum (Ta) or any other non-magnetic metallic layer separating the FL1 252 and the FL2 254.

The capping layer structure 260 does not include any tantalum (Ta) or any tantalum alloy. Specifically, the capping layer structure 260 is made of a first capping layer 262 that is made of ruthenium (Ru) and a second capping layer 264 that is made of platinum (Pt). In one implementation, the second capping layer 264 may be made of a noble material that does not oxidize. As the noble layers do not oxidize easily, they reduce the process variations during formation of the sensor structure that may occur due to the oxidization of a layer in the cap layer. Other materials that may be used in place of platinum may include, for example silver, gold, etc., that does not oxidize.

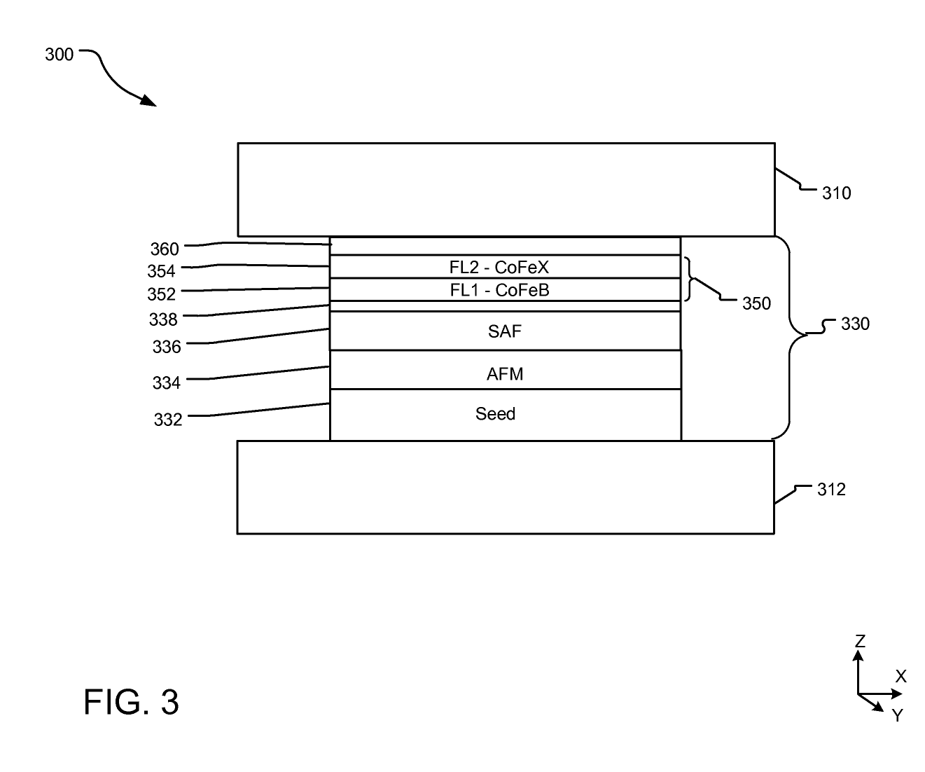

FIG. 3 illustrates an alternative example implementation of the MR sensor 300 including a free layer including a layer of alloyed material. The MR sensor 300 includes a sensor stack 330 located along a down-track (z axis) direction between a bottom shield 312 and a top shield 310. The sensor stack 330 includes a seed layer 332, an AFM layer 334, a SAF layer 336, a tunneling barrier layer 338, a free layer structure 350, and a capping layer structure 360. In the illustrated implementation, the free layer structure 350 includes a lower free layer FL1 352 that is made of CoFeB or CoFe/CoFeB layers and an upper free layer FL2 354 that is made of an alloy of a ferromagnetic material and a refractory material (X). Furthermore, the free layer structure 350 does not include any layer of tantalum (Ta) or any other non-magnetic metallic layer separating the FL1 352 and the FL2 354.

The capping layer structure 360 does not include any tantalum (Ta) or any tantalum alloy. Specifically, the capping layer structure 360 is made of a noble material, such as platinum (Pt). Specifically, the capping layer structure 360 may be made of a noble material that does not oxidize. As the noble layers do not oxidize easily, they reduce the process variations during formation of the sensor structure that may occur due to the oxidization of a layer in the cap layer. Other materials that may be used in place of platinum may include, for example silver, gold, etc., that does not oxidize.

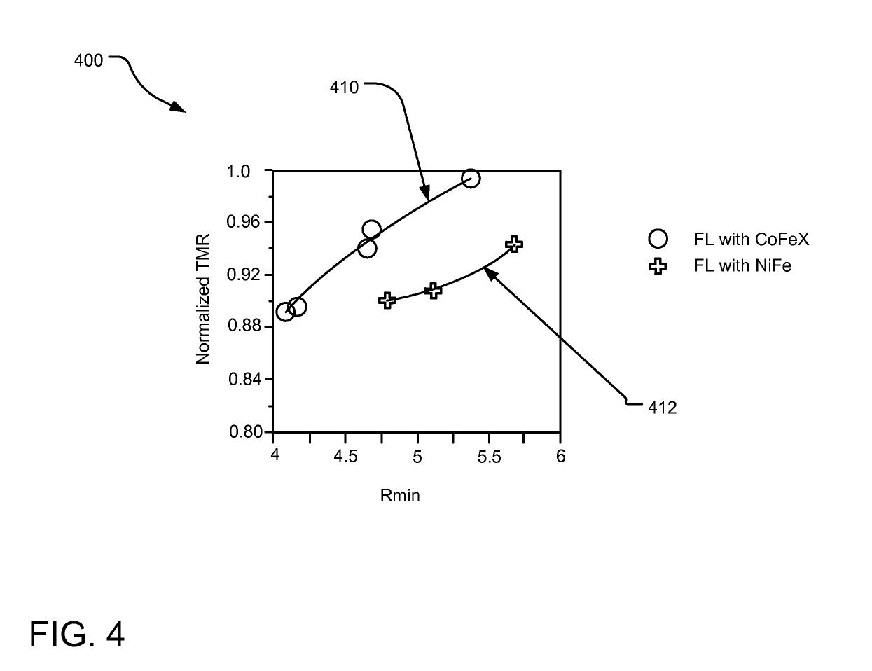

FIG. 4 illustrates an example graph 400 of normalized tunneling magneto-resistance (TMR) for an MR sensor disclosed herein. Specifically, the graph 400 illustrates the relation between normalized TMR (along the y-axis) as a function of sensor resistance (along the x-axis) for two different implementations of MR sensor. A first line 410 illustrates such relation between normalized TMR and sensor resistance (Rmin) for an MR sensor that includes a free layer with an alloy of a ferromagnetic material and a refractory material (X). A second line 412 illustrates such relation between normalized TMR and sensor resistance (Rmin) for an MR sensor that includes a free layer with NiFe. As shown by the graph 400, for each level of sensor resistance (Rmin), the MR sensor having a free layer with an alloy of a ferromagnetic material and a refractory material (X) provides higher TMR than the MR sensor with free layer including NiFe. By replacing the NiFe and therefore Ta from the MR sensor (line 412) with an alloy of a ferromagnetic material and a refractory material (X), such as CoFeX, the flux in the free layer can be increased by up to 30%, resulting in signal to noise ratio (SNR) gain of approximately over half dB.

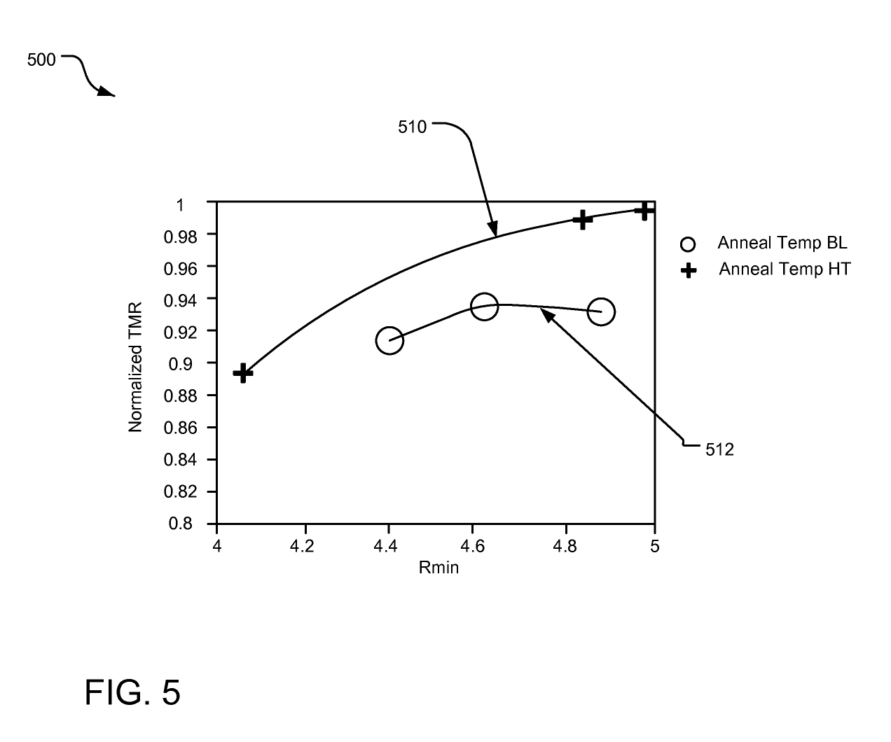

FIG. 5 illustrates an alternative example graph 500 of normalized TMR for an MR sensor disclosed herein. Specifically, the graph 500 illustrates the relation between normalized TMR (along the y-axis) as a function of sensor resistance (along the x-axis) for the implementation of MR sensor annealed at different temperatures. A first line 510 illustrates such relation between normalized TMR and sensor resistance (Rmin) for an MR sensor that includes a free layer with an alloy of a ferromagnetic material and a refractory material (X) and therefore, it is annealed at a higher temperature (HT). A second line 512 illustrates such relation between normalized TMR and sensor resistance (Rmin) for an MR sensor that includes a free layer with an alloy of a ferromagnetic material and a refractory material (X), and it is annealed at a lower temperature (BL). As shown by the graph 500, for each level of sensor resistance (Rmin), the MR sensor having a free layer with an alloy of a ferromagnetic material and a refractory material (X) that is annealed at a higher temperature provides higher TMR than the MR sensor is annealed at a lower temperature.

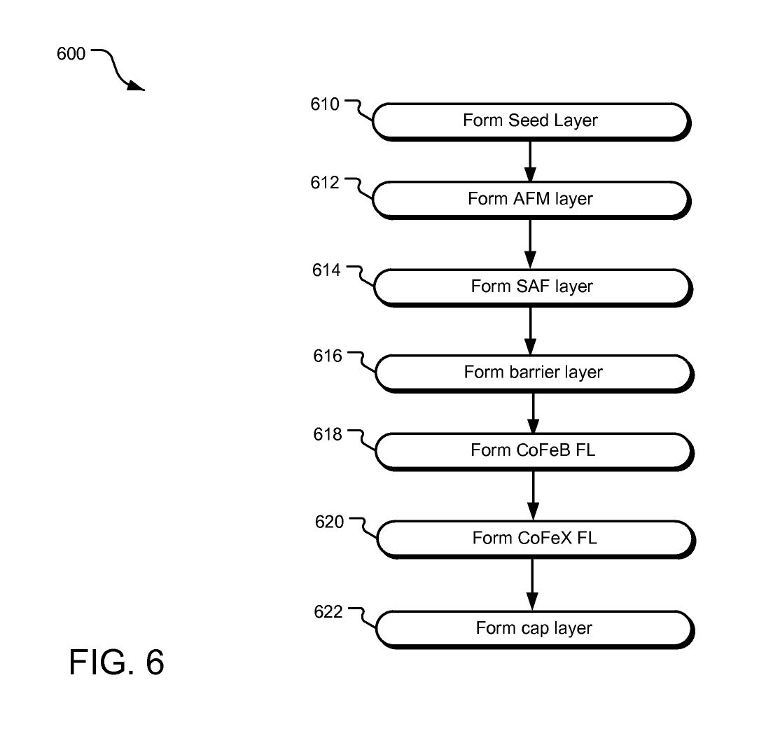

FIG. 6 illustrates example operations 600 for forming the MR sensor stack disclosed herein. An operation 610 forms a seed layer on a bottom shield. An operation 612 forms an AFM layer on the seed layer and subsequently, an operation 614 forms a SAF layer on the AFM layer. A tunneling barrier layer is formed by an operation 616. Operations 618 and 620 form a free layer structure of the sensor stack. Specifically, the operation 618 forms a first layer of CoFeB or CoFe/CoFeB layers adjacent or in contact with the tunneling barrier layer. The Operation 620 forms a second free layer of an alloy including a ferromagnetic material and a refractory material (X). Subsequently a cap layer is formed by an operation 622. The cap layer may include one layer of a noble material such as platinum or two layers with a ruthenium layer and a platinum layer.

The specific steps discussed with respect to each of the implementations disclosed herein are a matter of choice and may depend on the materials utilized and/or design criteria of a given system. The above specification, examples, and data provide a complete description of the structure and use of exemplary implementations of the invention. Since many implementations of the invention can be made without departing from the spirit and scope of the invention, the invention resides in the claims hereinafter appended.

What is claimed is:

1. A magnetoresistive (MR) sensor comprising:
a barrier layer; and
a free layer (FL) comprising a first layer (FL1) of CoFeB or CoFe/CoFeB adjacent to a barrier layer and a second layer (FL2) including a ferromagnetic material and a refractory material (X).

2. The MR sensor of claim 1, wherein the ferromagnetic material of the second layer is at least one of Co, Fe, and CoFe.

3. The MR sensor of claim 1, wherein the refractory material of the second layer is at least one of Ta, Nb, Hf, and Zr.

4. The MR sensor of claim 1, wherein the second layer is amorphous.

5. The MR sensor of claim 1, wherein the refractory material comprises less than 30 percent of material in the second layer.

6. The MR sensor of claim 1, wherein the first layer is in contact with a barrier layer and the second layer is in contact with the first layer.

7. The MR sensor of claim 1, wherein the second layer is adjacent a cap layer that does not include tantalum.

8. The MR sensor of claim 1, wherein the second layer is adjacent a cap layer that is made of a single layer of a non-oxidizable material.

9. The MR sensor of claim 1, wherein the second layer is adjacent a cap layer that is made of a single layer of at least one of Iridium, platinum, gold, silver, palladium, and rhodium.

10. A magnetoresistive (MR) sensor comprising:
a free layer comprising a first layer of CoFeB or CoFe/CoFeB and a second layer including a ferromagnetic material and a refractory material; and
a cap layer adjacent the second layer, wherein the cap layer does not include any tantalum or any tantalum alloy.

11. The MR sensor of claim 10, wherein the refractory material comprises less than 30 percent of material in the second layer.

12. The MR sensor of claim 10, wherein the cap layer is made of a single layer of a non-oxidizable material.

13. The MR sensor of claim 12, wherein the non-oxidizable material is at least one of platinum, iridium, palladium, rhodium, silver, and gold.

14. The MR sensor of claim 10, wherein the refractory material is at least one of Ta, Nb, Hf, and Zr.

15. The MR sensor of claim 10, wherein the first layer is in contact with the second layer.

16. The MR sensor of claim 10, wherein the free layer does not include any tantalum layer.

17. A magnetoresistive (MR) sensor comprising:
a barrier layer;
a cap layer; and
a free layer structure including first and second ferromagnetic layers adjacent to each other, wherein the first ferromagnetic layer is adjacent to the barrier layer and the second ferromagnetic layer is adjacent to the cap layer.

18. The MR sensor of claim 17, wherein the first ferromagnetic layer is made of CoFeB or CoFe/CoFeB and the second ferromagnetic layer is made of an alloy of a ferromagnetic material and a refractory material.

19. The MR sensor of claim 17, wherein the second ferromagnetic layer includes less than thirty percent of the refractory material.

20. The MR sensor of claim 17, wherein the cap layer is made of a single layer of a non-oxidizable material.
